(19) United States
(12) Patent Application Publication
(10) Pub. No.: US 2026/0010694 A1
(43) Pub. Date: Jan. 8, 2026

(54) METHODS, SYSTEMS, AND COMPUTER READABLE MEDIA FOR SCHEDULED TRAFFIC GENERATION AND TRANSMISSION IN ELECTRONICS DESIGN AUTOMATION (EDA) TEST ENVIRONMENTS

(71) Applicant: Keysight Technologies, Inc., Santa Rosa, CA (US)

(72) Inventors: Lucian Mogosanu, Bucharest (RO); Alice Florenta Suiu, Bucharest (RO); Daniel Marian Nicolescu, Bucharest (RO); Alexandru Nicolae, Corbeanca (RO)

(21) Appl. No.: 18/777,497

(22) Filed: Jul. 18, 2024

(30) Foreign Application Priority Data
Jul. 8, 2024 (RO) A2024 00400

(51) Int. Cl. G06F 30/31

(52) U.S. Cl. CPC G06F 30/31

(57) ABSTRACT

A method for scheduled traffic generation in an EDA test system includes receiving, by a test controller, at least one parameter associated with a scheduled transmission of emulated network traffic to an electronics design under test. The method further includes receiving, by the test controller and from an EDA test platform, a timestamp TO in an EDA emulator timing domain. The method further includes computing, based on the timestamp TO in the EDA emulator timing domain and the at least one parameter, a traffic launch timestamp in the EDA emulator timing domain and communicating the traffic launch timestamp and at least one test packet to the EDA emulator. The method further includes receiving, from the EDA emulator, an indication as to whether the EDA emulator successfully initiated transmission of the at least one test packet to an electronics design under test at a time indicated by the traffic launch timestamp.

### PRIORITY CLAIM

This application claims the priority benefit of Romanian Patent Application No. (Serial No. not yet assigned), filed Jul. 8, 2024, and entitled, “METHODS, SYSTEMS, AND COMPUTER READABLE MEDIA FOR SCHEDULED TRAFFIC GENERATION AND TRANSMISSION IN ELECTRONICS DESIGN AUTOMATION (EDA) TEST ENVIRONMENTS”, the disclosure of which is incorporated herein by reference in its entirety.

### TECHNICAL FIELD

The subject matter described herein relates to network traffic emulation. More particularly, the subject matter described herein relates to generating emulated network traffic, providing the traffic to an EDA emulator, and instructing the EDA emulator to send traffic to an electronics design under test at a scheduled time that adheres to a specified timing boundary in the timing domain of the EDA emulator.

### BACKGROUND

Electronics design automation refers to the process of designing integrated circuits using software tools, such as logic design, synthesis, and verification tools, that are used to design and test a proposed integrated circuit before the design is committed to hardware. One type of tool used in EDA is referred to as an EDA emulator. An EDA emulator emulates a hardware design so that the functionality and performance of the design can be tested prior to finalizing the design in hardware. In some cases, an EDA emulator consists of two parts: a transactor and a design under test (DUT). The transactor feeds traffic bit by bit to the DUT. For example, if the DUT is a design for a network adapter chip, the transactor may simulate Open Systems Interconnect (OSI) layers 1 and 2. The DUT is a gate-level implementation, e.g., written in register transfer level (RTL) code, of the design being evaluated. For example, in computer networking, the DUT may be an implementation of a network chip, such as an Ethernet chip.

One problem that may arise in testing an electronics design under tests is implementing scheduled traffic generation tests when the EDA emulator and the traffic generation system that generates test traffic to send to the EDA emulator operate in different timing domains. For example, it may be desirable to implement test traffic transmission at a scheduled time in the future, for example, to test the design under test's implementation of a standard, such as IEEE 802.1Qbv. However, there is no defined timing interface between network traffic generation platform, the EDA test platform, and the EDA emulator. Accordingly, there exists a need for improved methods, systems, and computer readable media for implementing scheduled traffic generation and transmission in EDA test environments.

### SUMMARY

A method for scheduled traffic generation in an electronics design automation (EDA) test environment includes receiving, by a test controller, at least one parameter associated with a scheduled transmission of emulated network traffic to an electronics design under test. The method further includes receiving, by the test controller and from an EDA test platform, a timestamp TO in an EDA emulator timing domain. The method further includes computing, by the test controller and based on the timestamp TO in the EDA emulator timing domain and the at least one parameter, a traffic launch timestamp in the EDA emulator timing domain. The method further includes communicating the traffic launch timestamp and at least one test packet to the EDA emulator. The method further includes receiving, from the EDA emulator, an indication as to whether the EDA emulator successfully initiated transmission of the at least one test packet to an electronics design under test at a time indicated by the traffic launch timestamp.

According to another aspect of the subject matter described herein, receiving the at least one parameter associated with the scheduled transmission of emulated network traffic includes receiving a transmit cycle time, which defines an 802.1Qbv alignment boundary, a delay value, and a transmit cycle offset value.

According to another aspect of the subject matter described herein, the method for scheduled traffic generation in an EDA test environment includes instructing, by the test controller, the EDA test platform to start a precision time protocol (PTP) synchronization process and wherein receiving the timestamp TO in the EDA emulator timing domain includes receiving the timestamp TO in response to the instructing of the EDA test platform to start the PTP synchronization process.

According to another aspect of the subject matter described herein, the method for scheduled traffic generation in an EDA test environment includes, at the test controller, treating the timestamp TO as a PTP timestamp.

According to another aspect of the subject matter described herein, computing the traffic launch timestamp includes adding the delay value to the timestamp TO received from the EDA test platform.

According to another aspect of the subject matter described herein, the method for scheduled traffic generation in an EDA test environment includes, at the test controller, receiving a hardware timestamp T1 from the EDA test platform and wherein computing the traffic launch timestamp includes computing an estimated time, where the estimated time is equal to a sum of the timestamp T0, the hardware timestamp T1, and the delay value, computing a remainder, where the remainder is equal to (estimated time) MOD (transmit cycle time), and computing the traffic launch timestamp as follows: traffic launch timestamp=(estimated time)+(transmit cycle time)−(remainder)+(transmit cycle offset).

According to another aspect of the subject matter described herein, communicating the at least one test packet and the traffic launch timestamp to the EDA emulator includes issuing, from the test controller and to the EDA test platform, a start scheduled traffic command including the traffic launch timestamp.

According to another aspect of the subject matter described herein, communicating the at least one test packet and the traffic launch timestamp to the EDA emulator includes generating, by the EDA test platform, a first test packet, embedding the traffic launch timestamp in the first test packet, and transmitting the first test packet from the EDA test platform to the EDA emulator.

According to another aspect of the subject matter described herein, communicating the at least one test packet and the traffic launch timestamp to the EDA emulator includes transmitting the at least one test packet and the traffic launch timestamp to a transactor of the EDA emulator.

According to another aspect of the subject matter described herein, communicating the at least one test packet and the traffic launch timestamp to the EDA emulator causes the EDA emulator to transmit the at least one test packet to the electronics design under test within an 802.1Qbv cycle.

According to another aspect of the subject matter described herein, a system for scheduled traffic generation in an electronics design automation (EDA) test environment is provided. The system includes a computing platform including at least one processor and a memory. The system further includes a test controller implemented by the at least one processor for receiving at least one parameter associated with a scheduled transmission of emulated network traffic to an electronics design under test, receiving a timestamp T0 in an EDA emulator timing domain, computing, based on the timestamp T0 in the EDA emulator timing domain and the at least one parameter, a traffic launch timestamp in the EDA emulator timing domain. The system further includes an EDA test platform for receiving the traffic launch timestamp, communicating the traffic launch timestamp and at least one test packet to the EDA emulator and receiving, from the EDA emulator, an indication as to whether the EDA emulator successfully initiated transmission of the at least one test packet to an electronics design under test at a time indicated by the traffic launch timestamp.

According to another aspect of the subject matter described herein, the at least one parameter associated with the scheduled transmission of emulated network traffic includes a transmit cycle time, which defines an 802.1Qbv alignment boundary, a delay value, and a transmit cycle offset value.

According to another aspect of the subject matter described herein, the test controller is configured to instruct the EDA test platform to start a precision time protocol (PTP) synchronization process and to receive the timestamp T0 in response to the instructing of the EDA test platform to start the PTP synchronization process.

According to another aspect of the subject matter described herein, the test controller is configured to treat the timestamp T0 as a PTP timestamp.

According to another aspect of the subject matter described herein, the test controller is configured to compute the traffic launch timestamp by adding the delay value to the timestamp T0 received from the EDA test platform.

According to another aspect of the subject matter described herein, the test controller is configured to receive a hardware timestamp T1 from the EDA test platform and the test controller is configured to compute the traffic launch timestamp by computing an estimated time, where the estimated time is equal to a sum of the timestamp T0, the hardware timestamp T1, and the delay value, computing a remainder, where the remainder is equal to (estimated time) MOD (transmit cycle time), and computing the traffic launch timestamp as follows: traffic launch timestamp=(estimated time)+(transmit cycle time)−(remainder)+(transmit cycle offset).

According to another aspect of the subject matter described herein, the test controller is configured to communicate the at least one test packet and the traffic launch timestamp to the EDA emulator by issuing, from the test controller and to the EDA test platform, a start scheduled traffic command including the traffic launch timestamp.

According to another aspect of the subject matter described herein, the EDA test platform is configured to communicate the at least one test packet and the traffic launch timestamp to the EDA emulator by generating a first test packet, embedding the traffic launch timestamp in the first test packet, and transmitting the first test packet to the EDA emulator.

According to another aspect of the subject matter described herein, communicating the at least one test packet and the traffic launch timestamp to the EDA emulator causes the EDA emulator to transmit the at least one test packet to the electronics design under test within an 802.1Qbv cycle.

According to another aspect of the subject matter described herein, one or more non-transitory computer readable media having stored thereon executable instructions that when executed by one or more processors of one or more computer control the one or more computers to perform steps includes receiving, by a test controller, at least one parameter associated with a scheduled transmission of emulated network traffic to an electronics design under test. The steps further include receiving, by the test controller and from an electronics design automation (EDA) test platform, a timestamp T0 in an EDA emulator timing domain. The steps further include computing, by the test controller and based on the timestamp T0 in the EDA emulator timing domain and the at least one parameter, a traffic launch timestamp in the EDA emulator timing domain. The steps further include communicating the traffic launch timestamp and at least one test packet to the EDA emulator. The steps further include receiving, from the EDA emulator, an indication as to whether the EDA emulator successfully initiated transmission of the at least one test packet to an electronics design under test at a time indicated by the traffic launch timestamp.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIG. 1 is a block diagram illustrating exemplary components of a system for scheduled traffic generation and transmission in an EDA test environment;

FIG. 2 is a computer screen shot of a user interface of a test controller for receiving parameters used by the test controller to compute a scheduled traffic start time for an EDA emulator to implement a scheduled test traffic transmission;

FIG. 3 is a timing diagram illustrating an example of 802.1Qbv alignment boundaries.

FIG. 4 is a block diagram illustrating exemplary operations for implementing scheduled traffic transmission to an electronics design under test;

FIG. 5 is a flow chart illustrating an exemplary state machine implemented by an EDA emulator in performing scheduled traffic transmission to an electronics design under test;

FIG. 6A is a packet flow diagram illustrating successful scheduled traffic generation using an EDA test platform and a transactor of an EDA emulator;

FIG. 6B is a packet flow diagram illustrating unsuccessful scheduled traffic generation using an EDA test platform and a transactor of an EDA emulator; and

FIG. 7 is a flow chart illustrating an exemplary process for scheduled traffic generation and transmission to an electronics design under test.

### DETAILED DESCRIPTION

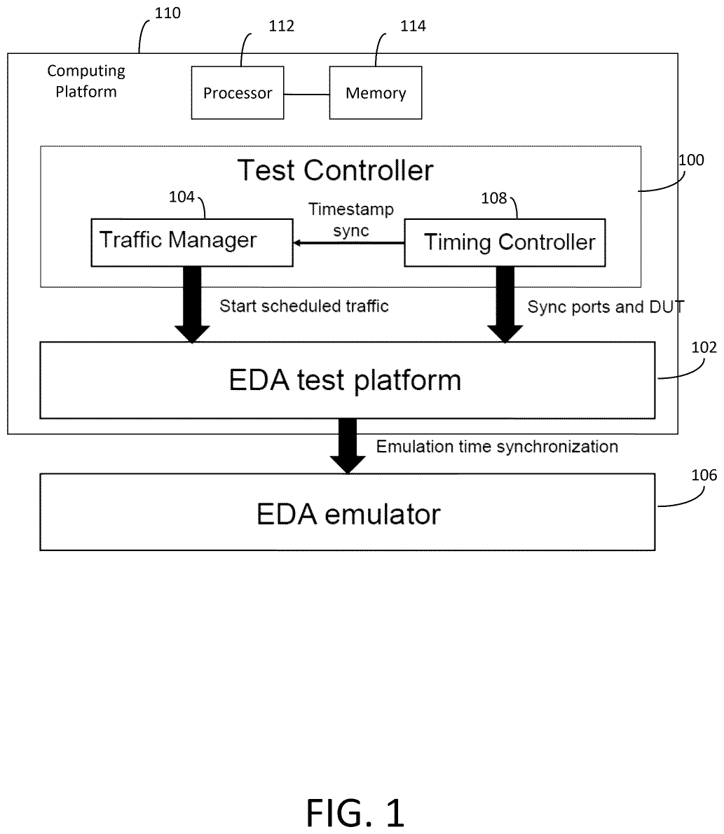

As stated above, one problem with implementing scheduled traffic generation and transmission in an EDA test environment is integrating operations performed by various components operating in different timing domains. FIG. 1 is a block diagram illustrating exemplary components of a system for scheduled traffic generation and transmission in an EDA test environment. In FIG. 1, a system for scheduled traffic generation and transmission in an EDA test environment includes a test controller 100 and an EDA test platform 102. Test controller 100 includes a traffic manager 104 that issues a start scheduled traffic command that instructs EDA test platform 102 to communicate the traffic launch timestamp and one or more data packets to EDA emulator 106 so that EDA emulator 106 will implement scheduled transmission of the one or more data packets to the electronics design under test.

Test controller 100 also includes a timing controller 108 that generates a traffic launch timestamp in a timing domain of EDA emulator 106, which indicates a time for EDA test platform 102 to start a scheduled transmission of traffic to an electronics design under test. Examples of how to computer the traffic launch timestamp will be described in more detail below. Test controller 100 and EDA test platform 102 may be implemented on a computer platform 110 including at least one processor 112 and a memory 114. It should be noted the computing platform on which test controller 100 and EDA test platform 102 are implemented is separate from the computing platform on which EDA emulator 106 is implemented, and, as a result, EDA emulator 106 operates in a different timing domain from test controller 100 and EDA test platform 102.

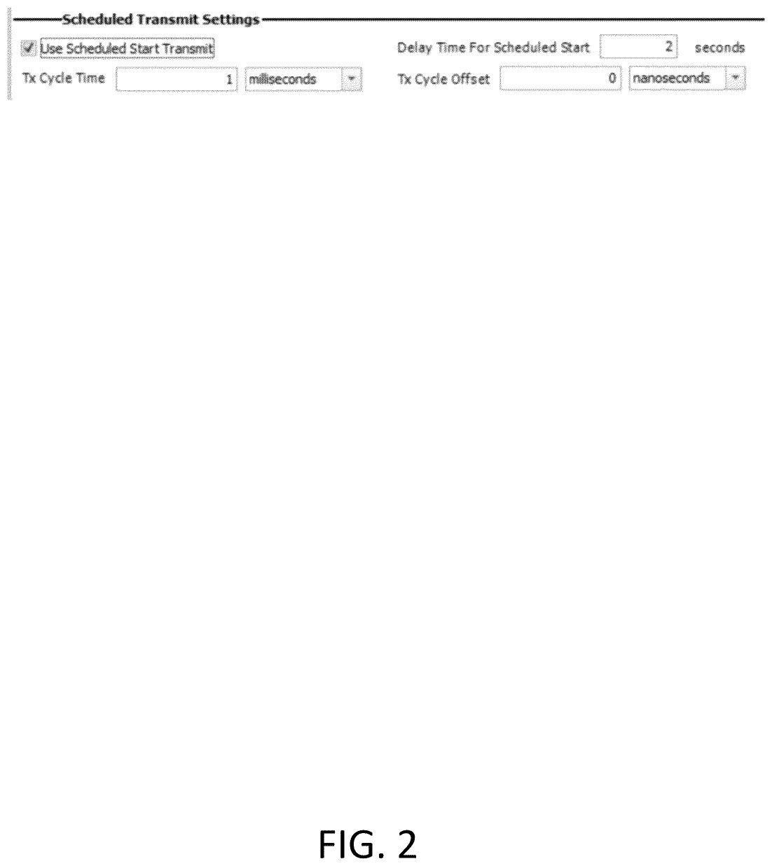

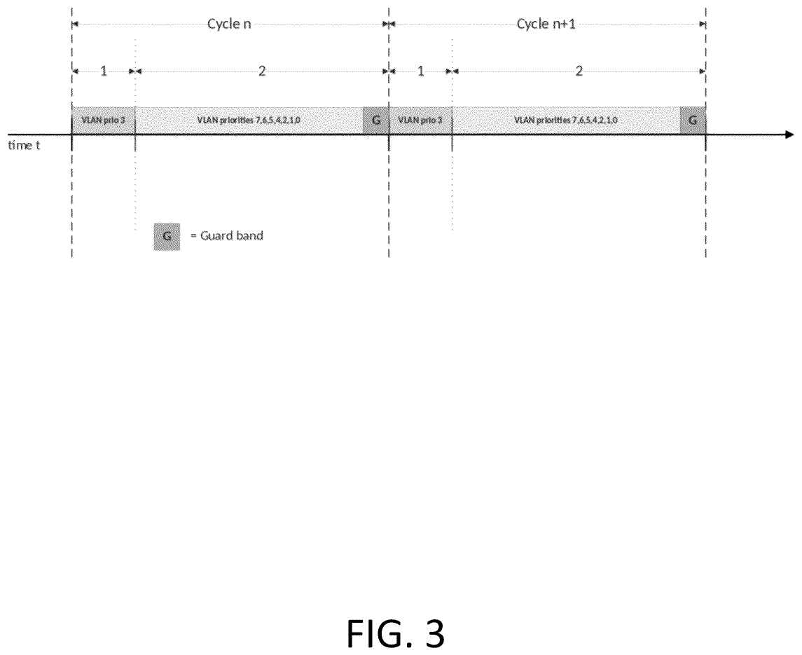

FIG. 2 is a computer screen shot of a user interface of a test controller for receiving parameters used by the test controller to compute a scheduled traffic start time for an EDA emulator to implement a scheduled test traffic transmission. Referring to FIG. 2, the user interface allows the user to specify a delay time for scheduled start, which is a time to wait before starting transmission of traffic. The delay time to scheduled start may be used to compensate for software delays. The user interface also allows the user to input a Tx cycle time, which can be a time associated with an 802.1Qbv alignment boundary. FIG. 3 is a timing diagram illustrating an example of 802.1Qbv alignment boundaries. In FIG. 3, 802.1Qbv transmission occurs in repeating cycles. FIG. 3 illustrates cycle n and cycle n+1. The Tx Cycle Time input in FIG. 2 defines the length or alignment boundary of the cycles illustrated in FIG. 3. During each cycle, EDA test platform 102 generates and transmits frames at different portions of the cycle according to virtual local area network (VLAN) priority. If transmission of a frame crosses a cycle boundary, a gate violation occurs. Test controller 100 may generate instructions for EDA test platform 102 to implement scheduled transmission of traffic to EDA emulator 106 where the transmitted frames are within 802.1Qbv cycle times (no gate violation) and/or outside of 802.1Qbv cycle times (gate violation).

Returning to FIG. 2, the user interface also allows the user to input a Tx cycle offset, which is used for compensation with respect to a generalized precision time protocol (gPTP) path delay. Once the user inputs the values in the user interface illustrated in FIG. 2, test controller 100 generates a launch timestamp and provides the traffic launch timestamp to EDA test platform 102.

Computation of the launch timestamp will be described in detail below.

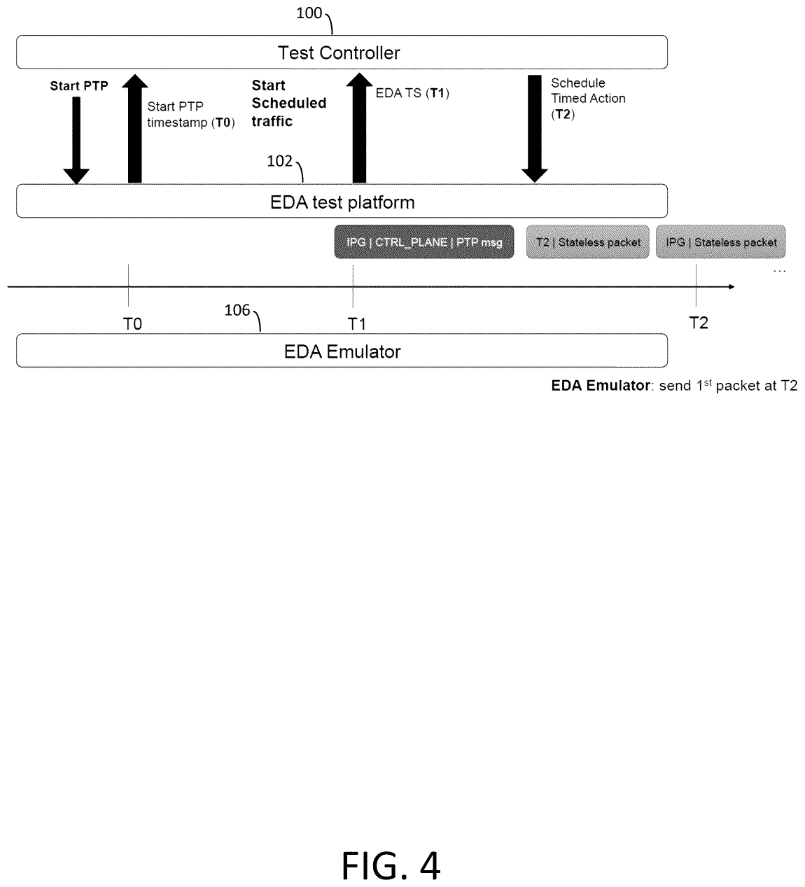

FIG. 4 is a block diagram illustrating exemplary operations for implementing scheduled traffic transmission to electronics design under test. Referring to the process flow illustrated in FIG. 4, to generated scheduled transmission of traffic, the following steps may be implemented:
1. At time T0, PTP is started. In particular, test controller 100 issues a start PTP command to EDA test platform 102 instructing EDA test platform 102 to start PTP time synchronization. EDA test platform 102 responds with a timestamp value in the timing domain of emulator 106. EDA emulator 106 sends periodic heartbeat messages to EDA test platform 102. The heartbeat messages may include timestamps in the timing domain of EDA emulator 106. As a result, EDA test platform 102 will always have an approximate view of a timestamp in the timing domain of EDA emulator 106. The timestamps received in the heartbeat messages may not be exactly equal to the current time in EDA emulator 100 but the timestamps are sufficiently accurate to use to compute the future traffic launch time, as described herein.
2. Test controller 100 receives the timestamp value from EDA test platform 102 and considers the timestamp value to be a PTP timestamp. The timestamp value received from EDA test platform 102 is illustrated as T0 in FIG. 3. Test controller 100 expects a PTP timestamp here, because it uses PTP to synchronize all the elements in the system (test ports and DUT). 802.1Qbv expects accurate (at least millisecond-level, in some cases microsecond-level) synchronization between elements, so the cycle start and end times must also be expressed as PTP timestamps.
In EDA testing, the PTP time is not “true” PTP time—the notion of epoch time (relative to Jan. 1 1970) does not make sense in the emulator time domain, so EDA test platform 102 “tricks” the test controller 100 into believing EDA test platform sent an actual PTP timestamp, by sending the timestamp T0 at a time when test controller 100 expects a PTP timestamp during the PTP synchronization process. 3. At time T1, a user issues a start scheduled traffic command to test controller 100 using the interface illustrated in FIG. 2. The start scheduled traffic command may be generated in response to the user inputting the parameter values illustrated in FIG. 2 and may include a Tx cycle time, a Tx cycle offset, and a delay value. In response to receiving the start scheduled traffic command, test controller 100 requests, from EDA test platform 102, a current value of a timestamp in the emulator timing domain. EDA test platform 102 responds with a timestamp relative to T0 in the emulator timing domain. This timestamp is illustrated in FIG. 4 as T1.
4. In response to receiving the current timestamp in the emulator timing domain, test controller 100 computes a timestamp T2, which is the time that the EDA test platform should start sending traffic to EDA emulator 106. Test controller 100 may compute T2 as follows:
T2 calculation: here test controller 100 has specific expectations:
   I. From the user, test controller 100 expects cycle time, delay and offset parameters, which are defined as described above with respect to FIG. 3. In summary, the cycle time, delay and offset parameters are defined as:
      (a) cycle time—the expected B cycle duration
      (b) delay—used to give EDA test platform 102 time to converge on the “start scheduled traffic” event
      (c) offset—used to introduce an additional delay relative to cycle start. The offset is normally used to compensate for PTP path delays (which should be measurable by test controller 100 after PTP synchronization is finished)
   II. From EDA test platform 102, test controller 100 expects the following parameters:
      (a) a PTP timestamp (T0) denoting the time of start of the test—We trick test controller 100 into believing that T0 is a PTP timestamp, but we're actually sending an emulation timestamp relative to a moment zero inside EDA emulator 106 (presumably, when EDA emulator 106 was started, the time was 0, and hence, T0 is a timestamp value in the timing domain of EDA emulator 106 relative to the start time of emulator 106 or some other epoch, depending on how EDA emulator 106 is configured or programmed.
      (b) a so-called “EDA” timestamp (T1) that is relative to T0
         This is an implementation detail: in post-silicon, T0 is an actual PTP timestamp while T1 is hardware timestamp (it has another reference point for T=0). Test controller 100 expects T0 (PTP timestamp) for the reason mentioned above. T0 is also the exact time when, inside of test platform 100, an internal hardware counter (HWC) is reset, i.e. HWC=0. When traffic is started, test controller 100 requests the current value of HWC from test platform 102. The current value of HWC is provided by test platform 102 as T1. Test controller 100 could use T0 (PTP timestamp in the past) and T1 (current value of HWC) to compute the current value of the PTP time,
         but there is probably a delay between the current time and the time when EDA emulator 106 is able to send the first packet. As a result, test delays are also taken into account here and, in fact, test controller 100 sends timestamp T2 (time in the future, aligned to the 802.1 Qbv cycle time), which is also a PTP timestamp
         in EDA time. EDA test platform 102 assumes that “PTP timestamp” is equivalent to “emulation time” (using the “trick” mentioned above).
In EDA testing, we need to trick test controller 100 into believing it received a hardware timestamp (we can perform this “PTP timestamp” <-> hardware timestamp conversion at any time).
To implement Qbv testing, test controller 100 computes the following:

EstimatedTime=T0+T1+delay
Remainder=EstimatedTime % cycle time, where “%” is the mod function, which returns the remainder of estimated time/cycle time.

T2=EstimatedTime+cycle time−Remainder+cycle offset
//add an extra cycle time and subtract remainder to align
//add cycle offset to compensate for e.g. path delays
3. At a time before T2, test controller 100 issues a start traffic command to EDA test platform 102 along with T2 as calculated above, where T2 is the scheduled traffic start time; EDA test platform 102 embeds T2 in the first data packet that EDA test platform 102 sends to EDA emulator 106. T2 is inserted in the first data packet instead of the inter-frame gap (IFG), by tagging the first data packet with a LAUNCH_TS metadata type, defined as follows:

#define PALLADIUM_LAUNCH_TS 0x80000000ull//Set by test controller (Request)/EDA test platform (Response)
4. EDA emulator 106 waits until T2 and starts sending the packet to the design under test at exactly T2.
5. EDA emulator 106 notifies EDA test platform 102 whether scheduled traffic start was successful. This operation may fail if the current time is after T2 (i.e., T2 is in the past at the time when the first data packet and the traffic launch timestamp are received by EDA emulator 106)

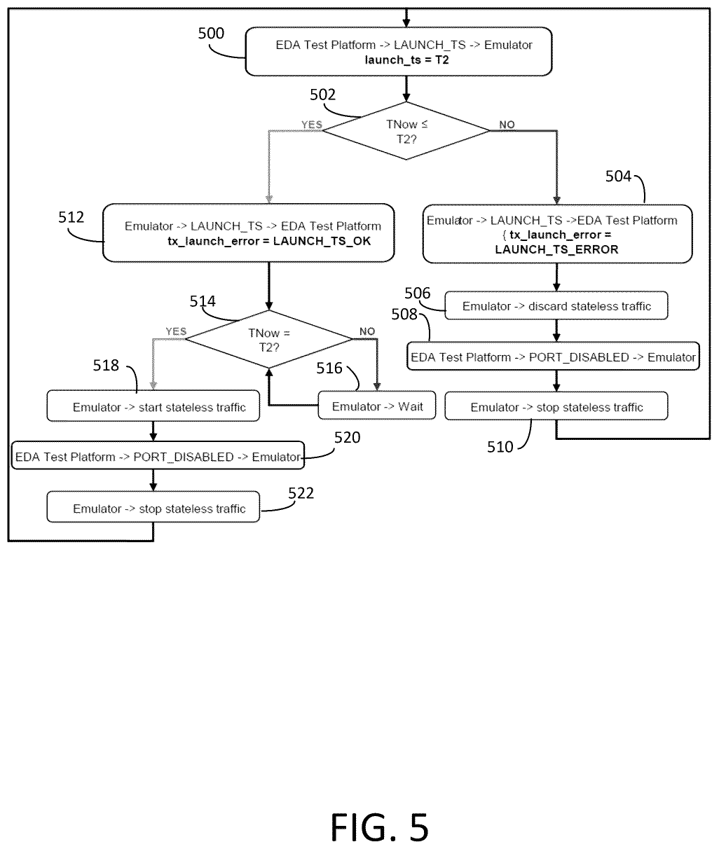

FIG. 5 is a flow chart illustrating an exemplary state machine implemented by an EDA emulator in implementing scheduled traffic transmission to an electronics design under test. Referring to FIG. 5, in step 500, EDA emulator 106 receives a packet transmitted from EDA test platform 102 with a launch timestamp of T2, where T2 is a timestamp computed in the timing domain of EDA emulator 106 based on the offset and delay values input by the user. In step 502, EDA emulator 106 determines whether the current time is before T2, i.e., whether the packet arrived at EDA emulator 106 before time T2. If the packet did not arrive at the EDA emulator 106 before time T2, control proceeds to step 504 where EDA emulator 106 determines that a launch timestamp error has occurred and notifies EDA test platform 102 of the launch timestamp error. Control then proceeds to step 506 where EDA emulator 106 discards the stateless traffic that it received from EDA test platform 102. In step 508, EDA test platform 102 communicates a port disabled message to EDA emulator 106. In step 510, EDA emulator 106 stops sending traffic to the electronics design under test.

Returning to step 502, if EDA emulator 106 determines that the packet arrived before time T2, control proceeds to step 512 where EDA emulator 106 communicates to EDA test platform 102 an indication that the launch timestamp for the scheduled traffic generation is okay. Control then proceeds to step 514 where EDA emulator 106 determines whether the current time is equal to T2. If the current time is not equal to T2, EDA emulator 106 waits, as indicated by step 516. When the current time equals T2, EDA emulator 106 proceeds to step 518 were EDA emulator 106 starts transmitting stateless traffic received from EDA test platform 102 to the electronics design under test. When EDA test platform 102 completes transmission of the traffic to EDA emulator 106, in step 520, EDA test platform 102 issues a port disabled message to EDA emulator 106. In step 512, EDA emulator 106 stops the flow of stateless traffic. Control then returns to step 500 to process the next scheduled traffic generation.

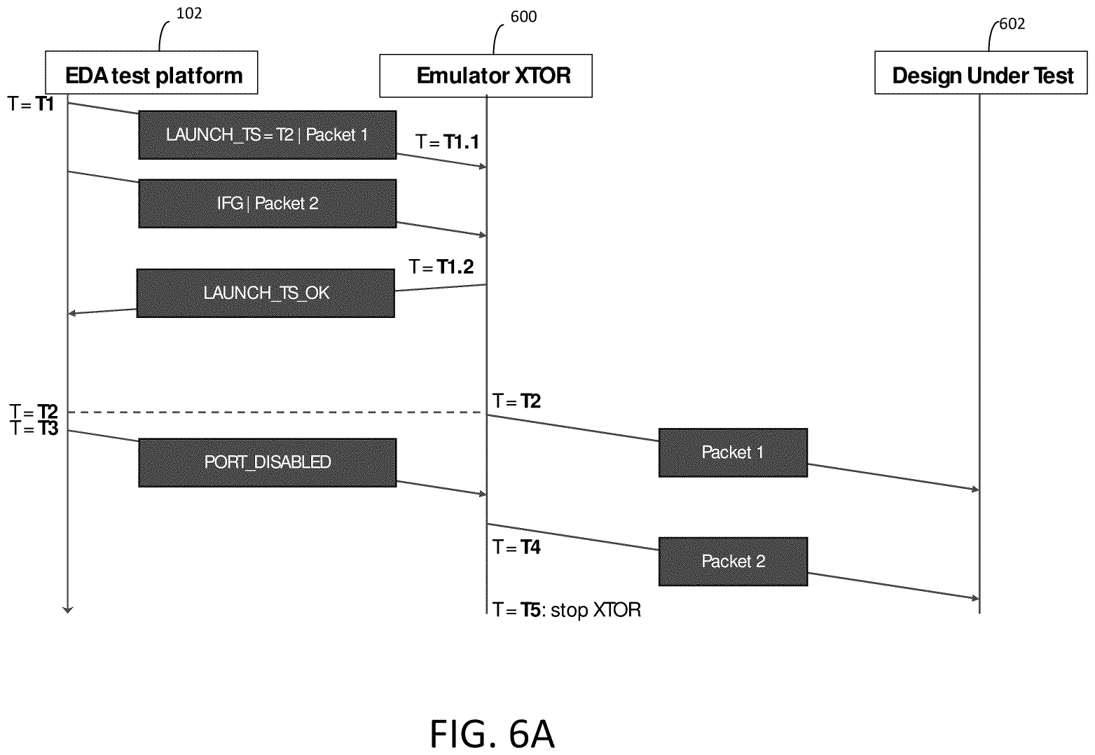

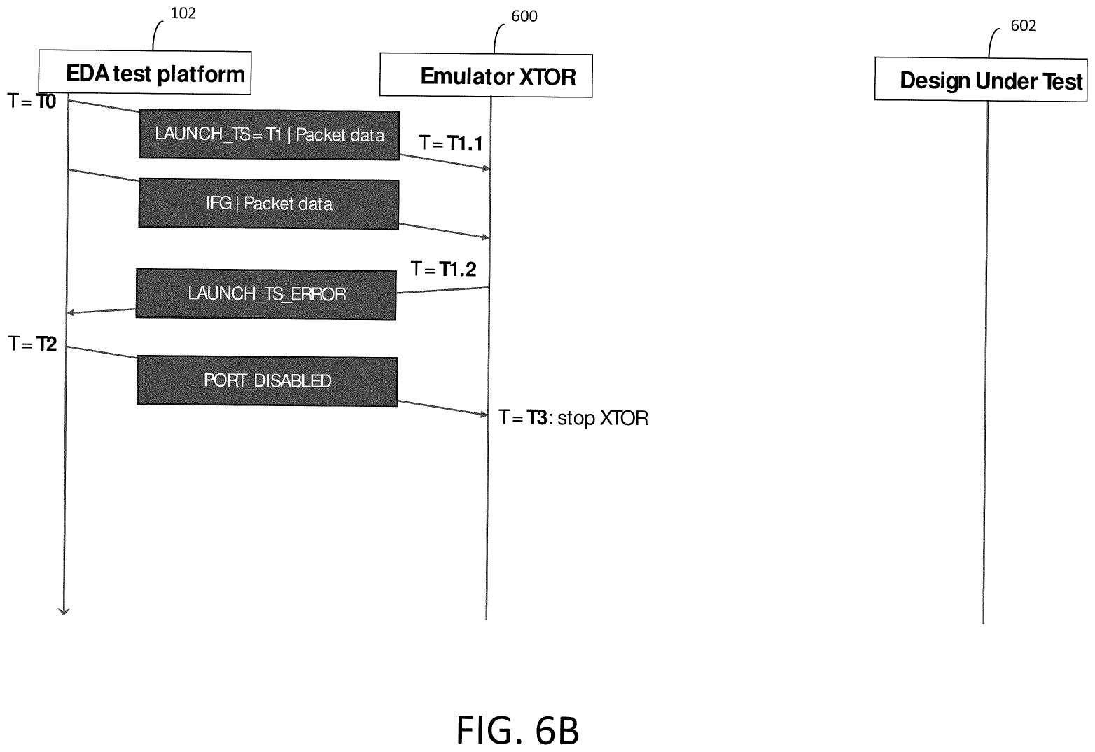

FIG. 6A is a packet flow diagram illustrating successful scheduled traffic generation using an EDA test platform and a transactor of an EDA emulator. Referring to FIG. 6A, at time T1, EDA test platform 102 communicates a first data packet and a launch timestamp to a transactor 600 of EDA emulator 106 instructing transactor 600 start sending packets to design under test 602 at a time T2. The data packet and the traffic launch timestamp arrive at transactor 600 at time T1.1, which is before time T2. EDA test platform 102 sends a second packet to transactor 600 as part of the scheduled traffic generation. At time T1.2, transactor 600 responds with a confirmation that traffic can be successfully started at time T2. At time T2, transactor 600 begins sending packets to design under test 602. The packet transmissions occur at times T2 and T4. At time T3, EDA test platform 102 transmits a port disabled message to transactor 600 indicating that EDA test platform 102 has no more traffic to send. EDA test platform 102 enqueues the port disabled message and, after sending the packet at time T5, stops sending traffic to design under test 602.

FIG. 6B is a packet flow diagram illustrating unsuccessful scheduled traffic generation using an EDA test platform and a transactor of an EDA emulator. Referring to FIG. 6B at time T1, EDA test platform 102 transmits the first data packet along with the traffic launch timestamp T2 to a transactor 600 of EDA emulator 106 instructing transactor 600 start sending packets to design under test 602 at a time T1. The data packet and the traffic launch timestamp arrive at transactor 600 at time T1.1, which is after time T1. The time T1 is a time calculated by EDA test platform 102 based on the emulator timestamp and the offset and delay parameters input by the user. In this case, the user may have misconfigured EDA test platform 102 by selecting a delay that is not long enough for the first data packet to arrive at transactor 600. EDA test platform 102 sends a second packet to transactor 600 as part of the scheduled traffic generation. At time T1.2, transactor 600 responds to the first data packet with a launch timestamp error message indicating that traffic generation cannot be started at the time T1. At time T2, EDA test platform 102 acknowledges the error and sends a port disabled message to transactor 600, indicating that EDA test platform 102 has stopped sending packets to transactor 600.

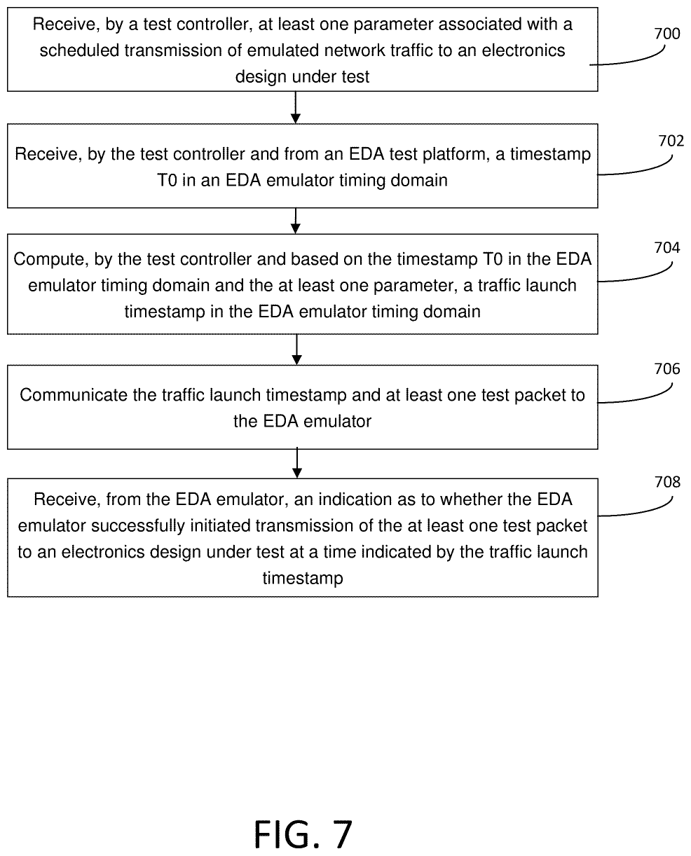

FIG. 7 is a flow chart illustrating an exemplary process for scheduled traffic generation and transmission to an electronics design under test. Referring to FIG. 7, in step 700, the process includes receiving, by a test controller, at least one parameter associated with a scheduled transmission of emulated network traffic to an electronics design under test. For example, a user may input, via a graphical user interface of test controller 100, a transmit cycle time, a transmit cycle offset, and a delay value associated with a scheduled transmission of traffic to an electronics design under test.

In step 702, the process further includes receiving, by the test controller and from an EDA test platform, a timestamp T0 in an EDA emulator timing domain. For example, test controller 100 may instruct EDA test platform to start the PTP time synchronization process. In response to receiving the instruction, EDA test platform may provide a timestamp T0 to test controller 100. The timestamp T0 is in the timing domain of EDA emulator 106. Because the timestamp T0 is received in response to a request to start PTP timing synchronization, test controller 100 treats the timestamp T0 as a PTP timestamp, i.e., a timestamp from a PTP master clock to which local clocks should be synchronized.

In step 704, the process further includes computing, by the test controller and based on the timestamp T0 in the EDA emulator timing domain and the at least one parameter, a traffic launch timestamp in the EDA emulator timing domain. For example, timing controller may compute the traffic launch timestamp T2 using the methodology described above.

In step 706, the process further includes communicating the traffic launch timestamp and at least one test packet to the EDA emulator. For example, test controller 100 may communicate the traffic launch timestamp to EDA test platform 102 along with a start scheduled traffic command. EDA test platform 102 receives the start scheduled traffic command and the traffic launch timestamp and communicates the traffic launch timestamp along with one or more test packets to EDA emulator 106. EDA emulator 106 receives the traffic launch timestamp and the test packets, waits until the current time equals T2, and, at the time T2, starts transmission of test packets to the electronics design under test. In one example, T2 is associated with an 802.1Qbv cycle so that EDA emulator 106 will transmit network traffic to the electronics device under test, which may be a design for a network processor design, within an 802.1Qbv cycle. In another example, the traffic launch timestamp may be a time so that one or more test ports of EDA test platform 102 will transmit emulated traffic to emulator 106 at the specified time.

In step 708, the process further includes receiving, from the EDA emulator, an indication as to whether the EDA emulator successfully initiated transmission of the at least one test packet to an electronics design under test at a time indicated by traffic launch timestamp. For example, EDA emulator 106 may communicate an indication to EDA test platform 102 an indication as to whether the scheduled transmission of traffic was successful.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for scheduled traffic generation in an electronics design automation (EDA) test environment, the method comprising:
receiving, by a test controller, at least one parameter associated with a scheduled transmission of emulated network traffic to an electronics design under test;
receiving, by the test controller and from an EDA test platform, a timestamp T0 in an EDA emulator timing domain;
computing, by the test controller and based on the timestamp T0 in the EDA emulator timing domain and the at least one parameter, a traffic launch timestamp in the EDA emulator timing domain;
communicating the traffic launch timestamp and at least one test packet to the EDA emulator; and
receiving, from the EDA emulator, an indication as to whether the EDA emulator successfully initiated transmission of the at least one test packet to an electronics design under test at a time indicated by the traffic launch timestamp.

2. The method of claim 1 wherein receiving the at least one parameter associated with the scheduled transmission of emulated network traffic includes receiving a transmit cycle time, which defines an 802.1Qbv alignment boundary, a delay value, and a transmit cycle offset value.

3. The method of claim 1 comprising, instructing, by the test controller, the EDA test platform to start a precision time protocol (PTP) synchronization process and wherein receiving the timestamp T0 in the EDA emulator timing domain includes receiving the timestamp T0 in response to the instructing of the EDA test platform to start the PTP synchronization process.

4. The method of claim 3 comprising, at the test controller, treating the timestamp T0 as a PTP timestamp.

5. The method of claim 2 wherein computing the traffic launch timestamp includes adding the delay value to the timestamp T0 received from the EDA test platform.

6. The method of claim 2 comprising, at the test controller, receiving a hardware timestamp T1 from the EDA test platform and wherein computing the traffic launch timestamp includes computing an estimated time, where the estimated time is equal to a sum of the timestamp T0, the hardware timestamp T1, and the delay value, computing a remainder, where the remainder is equal to (estimated time) MOD (transmit cycle time), and computing the traffic launch timestamp as follows:
traffic launch timestamp=(estimated time)+(transmit cycle time)−(remainder)+(transmit cycle offset).

7. The method of claim 1 wherein communicating the at least one test packet and the traffic launch timestamp to the EDA emulator includes issuing, from the test controller and to the EDA test platform, a start scheduled traffic command including the traffic launch timestamp.

8. The method of claim 1 wherein communicating the at least one test packet and the traffic launch timestamp to the EDA emulator includes generating, by the EDA test platform, a first test packet, embedding the traffic launch timestamp in the first test packet, and transmitting the first test packet from the EDA test platform to the EDA emulator.

9. The method of claim 1 wherein communicating the at least one test packet and the traffic launch timestamp to the EDA emulator includes transmitting the at least one test packet and the traffic launch timestamp to a transactor of the EDA emulator.

10. The method of claim 1 wherein communicating the at least one test packet and the traffic launch timestamp to the EDA emulator causes the EDA emulator to transmit the at least one test packet to the electronics design under test within an 802.1Qbv cycle.

11. A system for scheduled traffic generation in an electronics design automation (EDA) test environment, the system comprising:
a computing platform including at least one processor and a memory;
a test controller implemented by the at least one processor for receiving at least one parameter associated with a scheduled transmission of emulated network traffic to an electronics design under test, receiving a timestamp T0 in an EDA emulator timing domain, computing, based on the timestamp T0 in the EDA emulator timing domain and the at least one parameter, a traffic launch timestamp in the EDA emulator timing domain; and
an EDA test platform for receiving the traffic launch timestamp, communicating the traffic launch timestamp and at least one test packet to the EDA emulator and receiving, from the EDA emulator, an indication as to whether the EDA emulator successfully initiated transmission of the at least one test packet to an electronics design under test at a time indicated by the traffic launch timestamp.

12. The system of claim 11 wherein the at least one parameter associated with the scheduled transmission of emulated network traffic includes a transmit cycle time, which defines an 802.1Qbv alignment boundary, a delay value, and a transmit cycle offset value.

13. The system of claim 11 wherein the test controller is configured to instruct the EDA test platform to start a precision time protocol (PTP) synchronization process and to receive the timestamp T0 in response to the instructing of the EDA test platform to start the PTP synchronization process.

14. The system of claim 13 wherein the test controller is configured to treat the timestamp T0 as a PTP timestamp.

15. The system of claim 12 wherein the test controller is configured to compute the traffic launch timestamp by adding the delay value to the timestamp T0 received from the EDA test platform.

16. The system of claim 12 wherein the test controller is configured to receive a hardware timestamp T1 from the EDA test platform and the test controller is configured to compute the traffic launch timestamp by computing an estimated time, where the estimated time is equal to a sum of the timestamp T0, the hardware timestamp T1, and the delay value, computing a remainder, where the remainder is equal to (estimated time) MOD (transmit cycle time), and computing the traffic launch timestamp as follows:
traffic launch timestamp=(estimated time)+(transmit cycle time)−(remainder)+(transmit cycle offset).

17. The system of claim 11 wherein the test controller is configured to communicate the at least one test packet and the traffic launch timestamp to the EDA emulator by issuing, from the test controller and to the EDA test platform, a start scheduled traffic command including the traffic launch timestamp.

18. The system of claim 11 wherein the EDA test platform is configured to communicate the at least one test packet and the traffic launch timestamp to the EDA emulator by generating a first test packet, embedding the traffic launch timestamp in the first test packet, and transmitting the first test packet to the EDA emulator.

19. The system of claim 11 wherein communicating the at least one test packet and the traffic launch timestamp to the EDA emulator causes the EDA emulator to transmit the at least one test packet to the electronics design under test within an 802.1Qbv cycle.

20. One or more non-transitory computer readable media having stored thereon executable instructions that when executed by one or more processors of one or more computer control the one or more computers to perform steps comprising:
receiving, by a test controller, at least one parameter associated with a scheduled transmission of emulated network traffic to an electronics design under test;
receiving, by the test controller and from an electronics design automation (EDA) test platform, a timestamp T0 in an EDA emulator timing domain;
computing, by the test controller and based on the timestamp T0 in the EDA emulator timing domain and the at least one parameter, a traffic launch timestamp in the EDA emulator timing domain;
communicating the traffic launch timestamp and at least one test packet to the EDA emulator; and
receiving, from the EDA emulator, an indication as to whether the EDA emulator successfully initiated transmission of the at least one test packet to an electronics design under test at a time indicated by the traffic launch timestamp.
